(19) United States
(12) Patent Application Publication
(10) Pub. No.: US 2020/0176452 A1
(43) Pub. Date: Jun. 4, 2020

(54) MEMORY DEVICE AND METHOD OF FORMING THE SAME

(71) Applicant: NANYA TECHNOLOGY CORPORATION, New Taipei city (TW)

(72) Inventors: Chen-Lun TING, Taipei City (TW); Tseng-Fu LU, New Taipei City (TW); Wei-Chih WANG, Taoyuan City (TW)

(21) Appl. No.: 16/224,828

(22) Filed: Dec. 19, 2018

Related U.S. Application Data
(60) Provisional application No. 62/774,873, filed on Dec. 4, 2018.

(51) Int. Cl. H01L 27/108

(52) U.S. Cl. CPC H01L 27/10823; H01L 27/10876

(57) ABSTRACT

A memory device includes a substrate, a first gate structure, and a first oxide layer. The substrate has a first protruding portion and a second protruding portion adjacent to the first protruding portion. The first gate structure is on the substrate and between the first and second protruding portions. The first oxide layer is disposed between the substrate and the first gate structure, and includes a first portion and a second portion. The first portion is between the first gate structure and the first protruding portion, the second portion is between the first gate structure and the second protruding portion, and a thickness of the first portion is greater than a thickness of the second portion.

### CROSS-REFERENCE TO RELATED APPLICATION

This application claims the priority benefit of U.S. provisional application Ser. No. 62/774,873, filed on Dec. 4, 2018. The entirety of the above-mentioned patent application is hereby incorporated by references herein and made a part of specification.

### BACKGROUND

### Field of Invention

The present disclosure relates to a memory device and a method of forming the memory device.

### Description of Related Art

With the shrinkage of integration circuit devices, smaller active area makes leakage problems for a recess array become worse. Thus, the retention time of a dynamic random-access memory (DRAM) may degrade. Therefore, the leakage problems need to be avoided or reduced to improve the performance of a DRAM cell.

### SUMMARY

An aspect of the present disclosure is to provide a memory device.

According to some embodiments of the disclosure, the memory device includes a substrate, a first gate structure, and a first oxide layer. The substrate has a first protruding portion and a second protruding portion adjacent to the first protruding portion. The first gate structure is on the substrate and between the first and second protruding portions. The first oxide layer is disposed between the substrate and the first gate structure and includes a first portion and a second portion. The first portion is between the first gate structure and the first protruding portion, the second portion is between the first gate structure and the second protruding portion, and a thickness of the first portion is greater than a thickness of the second portion.

In some embodiments of the disclosure, the first protruding portion and the second protruding respectively have a first and second source/drain regions, and the first and second portions of the first oxide layer respectively extend to sidewalls of the first and second source/drain regions.

In some embodiments of the disclosure, the first portion of the first oxide layer extends to a bottom of the first gate structure.

In some embodiments of the disclosure, the memory device further includes a dielectric layer on the first gate structure, and the first and second portions of the first oxide layer extend to sidewalls of the dielectric layer.

In some embodiments of the disclosure, the dielectric layer is between the first and second portions of the first oxide layer.

In some embodiments of the disclosure, the first protruding portion and the second protruding portion respectively have a first and second source/drain regions, and each of the first and second portions of the first oxide layer is between the dielectric layer and one of the first and second source/drain regions.

In some embodiments of the disclosure, the substrate further has a third protruding portion adjacent to the second protruding portion, and the memory device further includes a second gate structure and a second oxide layer. The second gate structure is on the substrate and between the second and third protruding portions. The second oxide layer is disposed between the substrate and the second gate structure, and includes a first portion and a second portion, and the first and second portions of the second oxide layer have different thickness.

In some embodiments of the disclosure, the first portion of the second oxide layer is between the second gate structure and the third protruding portion, the second portion of the second oxide layer is between the second gate structure and the second protruding portion, and a thickness of the first portion of the second oxide layer is greater than a thickness of the second portion of the second oxide layer.

In some embodiments of the disclosure, the third protruding portion has a third source/drain region, and the first and second portions of the second oxide layer respectively extend to sidewalls of the third source/drain region and the second source/drain region.

In some embodiments of the disclosure, the second portion of the first oxide layer and the second portion of the second oxide layer are located on two opposite sidewalls of the second protruding portion.

Another aspect of the present disclosure is to provide a method of forming a memory device.

According to some embodiments of the disclosure, the method of forming a memory device includes forming a first trench and a second trench in a substrate such that each of the first and second trenches has a first sidewall and a second sidewall opposite the first sidewall, and the second sidewalls are between the first sidewalls; forming a mask layer to cover the first trench and the second trench; performing an ion implantation into first sidewalls of the first and second trenches; removing the mask layer; and forming a first oxide layer and a second oxide layer respectively in the first and second trenches such that thicknesses of the first and second oxide layers on the first sidewalls of the first and second trenches are greater than thicknesses of the first and second oxide layers on the second sidewalls of the first and second trenches.

In some embodiments of the disclosure, forming the mask layer further includes forming the mask layer over a top surface of the substrate; and polishing the mask layer.

In some embodiments of the disclosure, forming the mask layer further includes removing the mask layer not covered by the photoresist layer after forming the photoresist layer.

In some embodiments of the disclosure, forming the mask layer further includes removing the photoresist layer after performing the ion implantation.

In some embodiments of the disclosure, the ion implantation is performed by using fluorine.

Another aspect of the present disclosure is to provide a method of forming a memory device.

According to some embodiments of the disclosure, the method of forming a memory device includes forming a first trench and a second trench in a substrate such that each of the first and second trenches has a first sidewall and a second sidewall opposite the first sidewall, and the second sidewalls are between the first sidewalls; forming a first oxide layer in the first trench and a second oxide layer in the second trench; forming a mask layer and a photoresist layer to cover the second sidewalls of the first and second trenches; removing the first and second oxide layers on the first sidewalls; forming a third oxide layer and a fourth oxide layer respectively on the first sidewalls such that a thickness of the third oxide layer is greater than a thickness of the first oxide layer, and a thickness of the fourth oxide layer is greater than a thickness of the second oxide layer; and removing the mask layer and the photoresist layer.

In some embodiments of the disclosure, forming the mask layer and the photoresist layer further includes forming the mask layer over the first oxide layer and the second oxide layer; and polishing the mask layer.

In some embodiments of the disclosure, forming the mask layer and the photoresist layer further includes forming the photoresist layer on the mask layer that covers the second sidewalls of the first and second trenches after polishing the mask layer.

In some embodiments of the disclosure, forming the mask layer and the photoresist layer further includes removing the mask layer not covered by the photoresist layer after forming the photoresist layer.

In the aforementioned embodiments, the gate induced drain leakage (GIDL) of recessed array (e.g., the buried first and second gate structures) can be suppressed by the thicker first portions of the first oxide layer and the second oxide layer. Therefore, the retention time of the memory device can be improved.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a memory device according to some embodiments of the present disclosure.

FIG. 2 is a flow chart of a method of forming a memory device according to some embodiments of the present disclosure.

FIGS. 3-10 are cross-sectional views of a method of forming a memory device at different mediate stages according to some embodiments of the present disclosure.

FIG. 11 is a flow chart of a method of forming a memory device according to some embodiments of the present disclosure.

FIGS. 12-19 are cross-sectional views of a method of forming a memory device at different mediate stage according to some embodiments of the present disclosure s.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

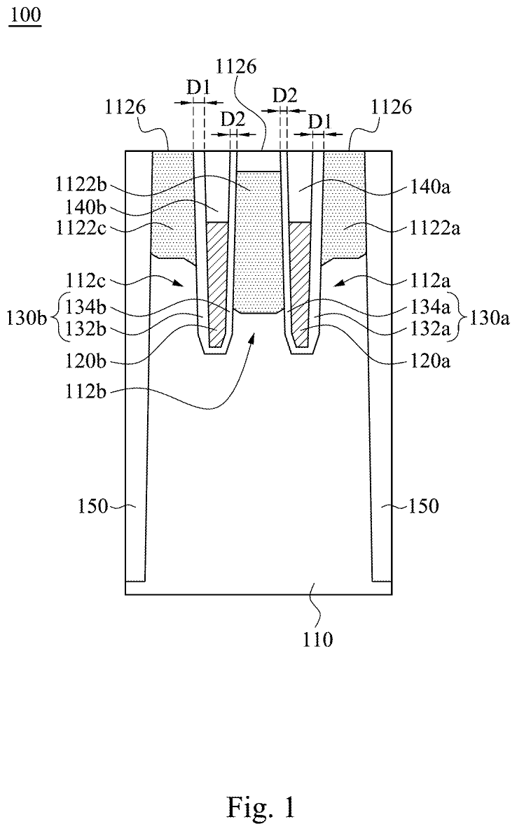

FIG. 1 is a cross-sectional view of a memory device 100 according to some embodiments of the present disclosure. The memory device 100 includes a substrate 110, a first gate structure 120a, a second gate structure 120b, a first oxide layer 130a, and a second oxide layer 130b. In some embodiments, the memory device 100 is a dynamic random-access memory device.

The substrate 110 includes a first protruding portion 112a, a second protruding portion 112b, and a third protruding portion 112c. The second protruding portion 112b is adjacent to and between the first protruding portion 112a and the third protruding portion 112c. The first, second, and third protruding portions 112a, 112b, and 112c respective have a first, second, and third source/drain regions 1122a, 1122b, and 1122c thereon.

The first gate structure 120a is on the substrate 110 and between the first protruding portion 112a and the second protruding portion 112b. The second gate structure 120b is on the substrate 110 and between the second protruding portion 112b and the third protruding portion 112c.

The first oxide layer 130a is disposed between the substrate 110 and the first gate structure 120a, and surrounds the first gate structure 120a. The second oxide layer 130b is disposed between the substrate 110 and the second gate structure 120b, and surrounds the second gate structure 120b.

The first oxide layer 130a includes a first portion 132a and a second portion 134a. The first portion 132a of the first oxide layer 130a is between the first gate structure 120a and the first protruding portion 112a of the substrate 110, and the second portion 134a of the first oxide layer 130a is between the first gate structure 120a and the second protruding portion 112b of the substrate 110.

The second oxide layer 130b includes a first portion 132b and a second portion 134b. The first portion 132b of the second oxide layer 130b is between the second gate structure 120b and the third protruding portion 112c of the substrate 110, and the second portion 134b of the second oxide layer 130b is between the second gate structure 120b and the second protruding portion 112b of the substrate 110.

Each of the first portion 132a of the first oxide layer 130a and the first portion 132b of the second oxide layer 130b has a thickness D1. Each of the second portion 134a of the first oxide layer 130a and the second portion 134b of the second oxide layer 130b has a thickness D2. The thickness D1 of the first portions 132a, 132b is greater than the thickness D2 of the second portions 134a, 134b. The second portion 134a of the first oxide layer 130a and the second portion 134b of the second oxide layer 130b are located on two opposite sidewalls of the second protruding portion 112b.

Accordingly, the gate induced drain leakage (GIDL) of recessed array (e.g., the buried first and second gate structures 120a and 120b) can be suppressed by the thicker first portions 132a and 132b of the first oxide layer 130a and the second oxide layer 130b. Therefore, the retention time of the dynamic random-access memory device 100 can be improved.

In some embodiments, the memory device 100 further includes a first dielectric layer 140a and a second dielectric layer 140b. The first dielectric layer 140a is disposed on the first gate structure 120a and between the first protruding portion 112a and the second protruding portion 112b. The second dielectric layer 140b is disposed on the second gate structure 120b and between the second protruding portion 112b and the third protruding portion 112c.

The first portion 132a of the first oxide layer 130a extends to a sidewall of the first source/drain region 1122a and a sidewall of the first dielectric layer 140a. The second portion 134a of the first oxide layer 130b extends to a sidewall of the second source/drain region 1122b and a sidewall of the first dielectric layer 140a. In other words, the first portion 132a of the first oxide layer 130a is located between the first source/drain region 1122a and the first dielectric layer 140a, and the second portion 134a of the first oxide layer 130b is located between the second source/drain region 1122b and the first dielectric layer 140a.

The first portion 132b of the second oxide layer 130b extends to a sidewall of the third source/drain region 1122c and a sidewall of the second dielectric layer 140b. The second portion 134b of the second oxide layer 130b extends to a sidewall of the second source/drain region 1122b and a sidewall of the second dielectric layer 140b. In other words, the first portion 132b of the second oxide layer 130b is located between the third source/drain region 1122c and the second dielectric layer 140b. The second portion 134b of the second oxide layer 130b is located between the second source/drain region 1122b and the second dielectric layer 140b.

The memory device 100 further includes shallow-trench isolations (STI) 150 respectively adjacent to the first protruding portion 112a and the third protruding portion 112c of the substrate 110. Contact structures may further disposed on the first source/drain region 1122a, the second source/drain region 1122b, and the third source/drain region 1122c. Moreover, a bit line may be formed above the second protruding portion 112b. Capacitors may be formed above the contact structures. In the present embodiment, the first portion 132a of the first oxide layer 130a that has thicker thickness D1 and the STI 150 at right side of FIG. 1 are respectively located at two opposite sides of the first protruding portion 112a. The first portion 132b of the second oxide layer 130b that has thick thickness D1 and the STI 150 at left side of FIG. 1 are respectively located at two opposite sides of the third protruding portion 112c.

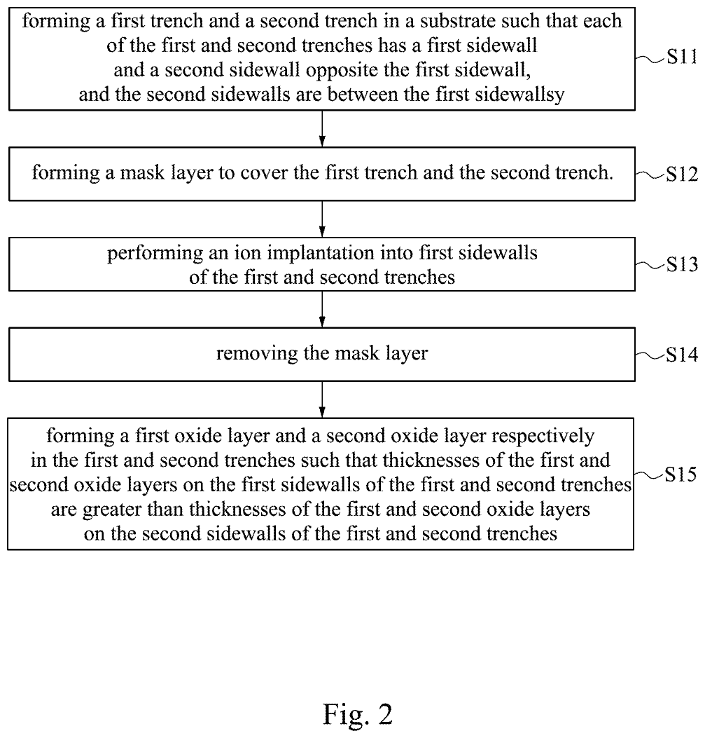

FIG. 2 is a flow chart of a method of forming a memory device according to some embodiments of the present disclosure. The method starts with step S11 in which a first trench and a second trench are formed in a substrate such that each of the first and second trenches has a first sidewall and a second sidewall opposite the first sidewall, and the second sidewalls are between the first sidewalls. Thereafter, in step S12, a mask layer is formed to cover the first trench and the second trench. Next, in step S13, an ion implantation is performed into first sidewalls of the first and second trenches. Afterwards, in step S14, the mask layer is removed. Subsequently, in step S15, a first oxide layer and a second oxide layer are formed respectively in the first and second trenches such that thicknesses of the first and second oxide layers on the first sidewalls of the first and second trenches are greater than thicknesses of the first and second oxide layers on the second sidewalls of the first and second trenches. In the following description, the aforementioned steps will be described in detail.

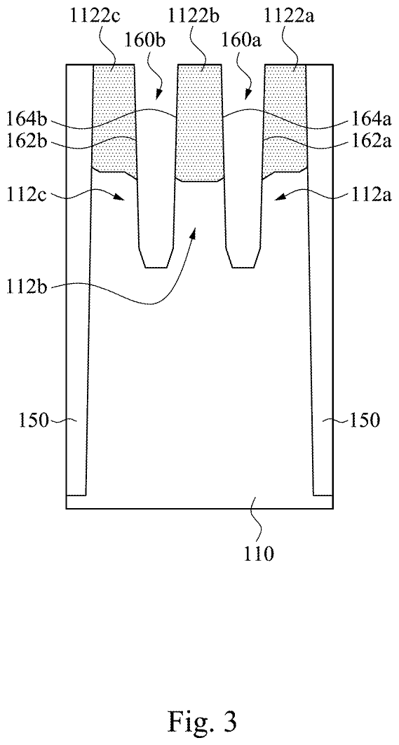

FIGS. 3-10 are cross-sectional views of a method of forming a memory device 100 at different mediate stages according to some embodiments of the present disclosure. Reference is made to FIG. 3 and step S11 of FIG. 2. A first trench 160a and a second trench 160b are formed in the substrate 110. The first trench 160a has a first sidewall 162a and a second sidewall 164a that is opposite to the first sidewall 162a, and the second trench 160b has a first sidewall 162b and a second sidewall 164b that is opposite to the first sidewall 162b. The second sidewall 164a of the first trench 160a and the second sidewall 164b of the second trench 160b are between the first sidewall 162a of the first trench 160a and the first sidewall 162b of the second trench 160b. In some embodiments, the STIs 150 are formed on the substrate 110, and the first trench 160a and the second trench 160b are between the two STIs 150.

The first trench 160a and the second trench 160b separate a top portion of the substrate 110 into the first protruding portion 112a, the second protruding portion 112b, and the third protruding portion 112c, in which the first, second, and third protruding portions 112a, 112b, and 112c respectively have the first, second, and third source/drain regions 1122a, 1122b, and 1122c thereon.

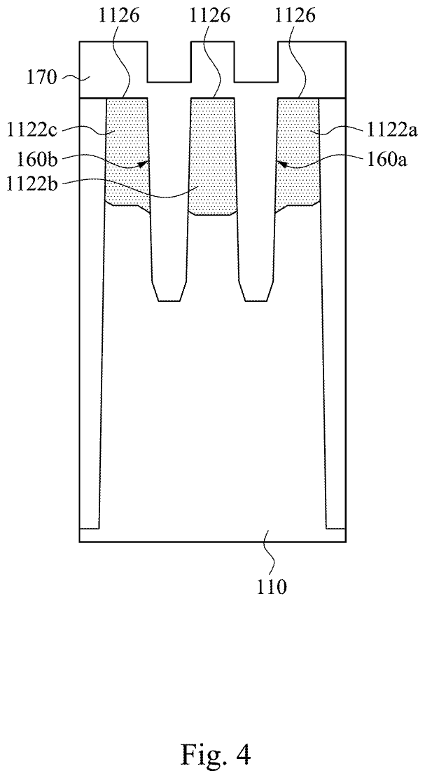

Reference is made to FIG. 4 and step S12 of FIG. 2. A mask layer 170 is formed to cover the first trench 160a and the second trench 160b, and is over the first source/drain region 1122a, the second source/drain region 1122b, and the third source/drain region 1122c. In other words, the mask layer 170 is over a top surface 1126 of the substrate 110. In some embodiments, the mask layer 170 is made of a material including nitride, but the present disclosure is not limited in this regard.

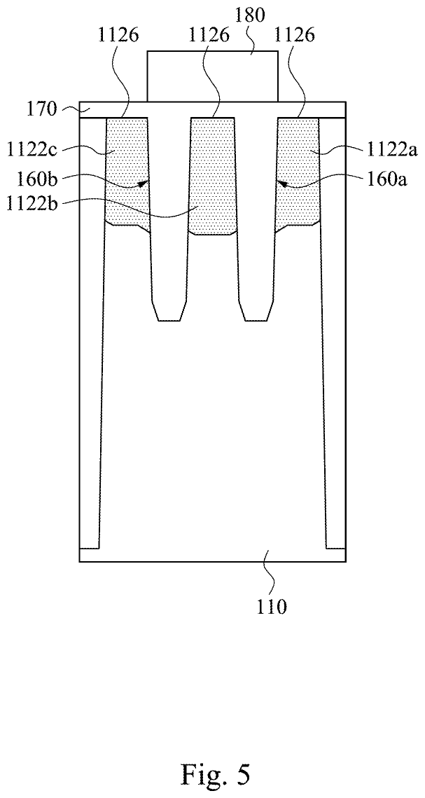

Reference is made to FIG. 5. The mask layer 170 is polished by chemical-mechanical planarization (CMP), while the top surface 1126 of the substrate 110 is still covered by the mask layer 170. After the mask layer 170 is polished, a photoresist layer 180 is formed on the mask layer 170. The photoresist layer 180 covers a portion of the mask layer 170 overlying the first trench 160a, the second 160b, and the second source/drain region 1122b.

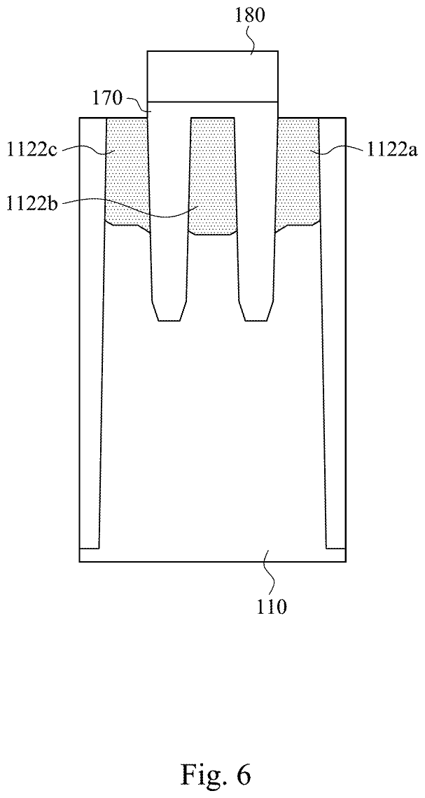

Reference is made to FIG. 6. After the photoresist layer 180 is formed, the portion of the mask layer 170 overlying the first source/drain region 1122a and the third source/drain region 1122c are removed by etching. In other words, the mask layer 170 that is not covered by the photoresist layer 180 is removed.

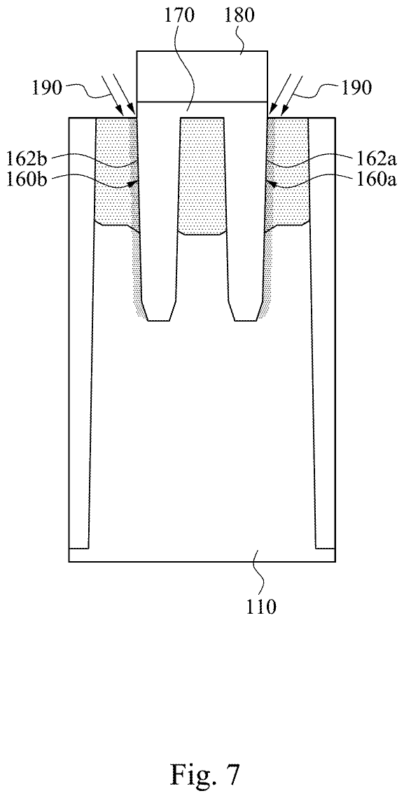

Reference is made to FIG. 7 and step S13 of FIG. 2. An ion implantation 190 is performed into the first sidewall 162a of the first trench 160a and the first sidewall 162b of the second trench 160b. In the present embodiment, the ion implantation 190 is performed by using fluorine. In some embodiments, the implantation concentration may be in a range from about 1×10¹³ to about 1×10¹⁵ (atoms/cm²), and the implantation energy may be in a range from about 10 k eV to about 20 k eV to keep the fluorine ions more concentrated on the first sidewalls 162a, 162b. Therefore, the fluorine ions may be selectively implanted only into the first sidewalls 162a, 162b by using the mask layer 170 and the photoresist layer 180.

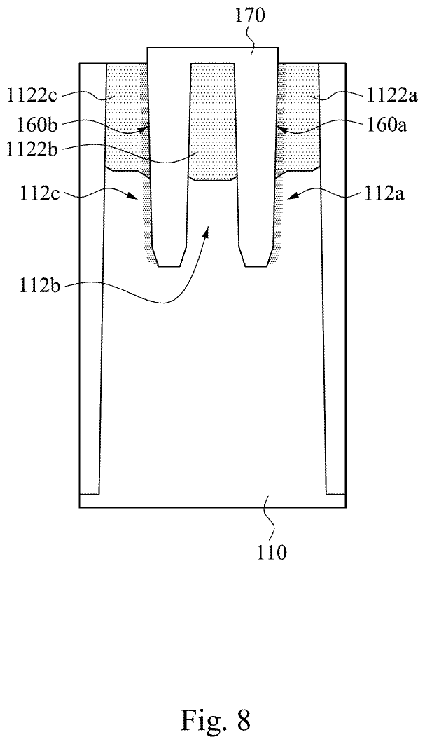

Reference is made to FIG. 7 and FIG. 8. After the ion implantation 190 is performed, the photoresist layer 190 is removed.

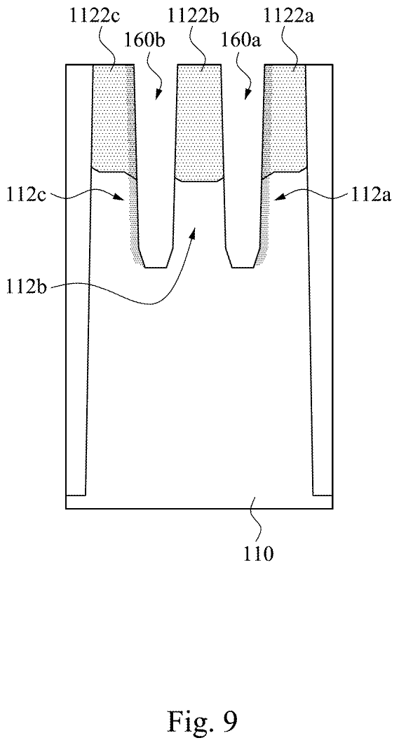

Reference is made to FIG. 8, FIG. 9 and step S14 of FIG. 2. The mask layer 170 is removed after the photoresist layer 190 is removed. Therefore, the first protruding portion 112a, the first source/drain region 1122a, the second protruding portion 112b, and the second source/drain region 1122b in the first trench 160a are exposed. The second protruding portion 112b, the second source/drain region 1122b, the third protruding portion 112c, and the third source/drain region 1122c in the second trench 160b are exposed.

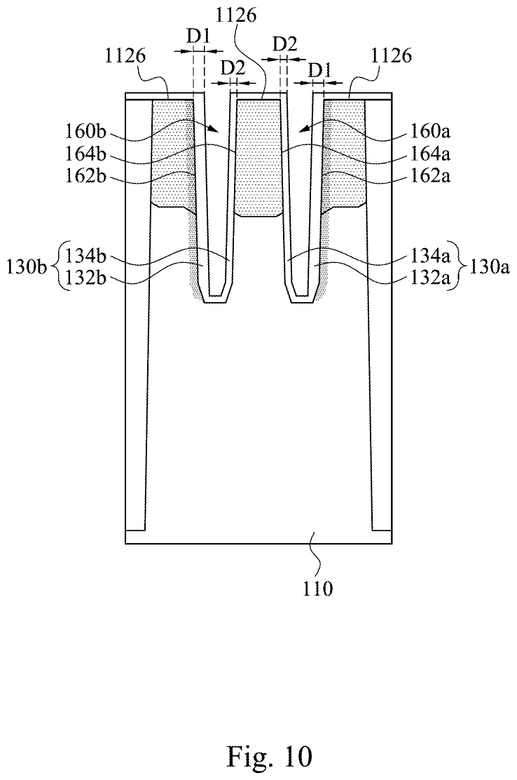

Reference is made to FIG. 10 and step S15 of FIG. 2. The first oxide layer 130a and the second oxide layer 130b are respectively formed in the first trench 160a and the second trench 160b. The first oxide layer 130a includes a first portion 132a located on the first sidewall 162a of the first trench 160a, and includes a second portion 134a located on the second sidewall 164a of the first trench 160a. The second oxide layer includes a first portion 132b located on the first sidewall 162b of the second trench 160b, and includes a second portion 134b located on the second sidewall 164b of the second trench 160b.

Each of the first portion 132a of the first oxide layer 130a and the first portion 132b of the second oxide layer 130b has a thickness D1. Each of the second portion 134a of the first oxide layer 130a and the second portion 134b of the second oxide layer 130b has a thickness D2.

The first sidewalls 162a, 162b of the first protruding portion 112a and the third protruding portion 112c that containing fluorine may promote the oxidation reaction such that thicker oxide layer may be formed on the first sidewalls 162a, 162b. Accordingly, the thickness D1 of the first portions 132a, 132b is greater than the thickness D2 of the second portions 134a, 134b.

In the subsequent process, the first gate structure 120a and the second gate structure 120b of FIG. 1 may be respectively formed in the first trench 160a and the second trench 160b, and then the first dielectric layer 140a and the second dielectric layer 140b of FIG. 1 may be respectively formed on the first gate structure 120a and the second gate structure 120b, thereby covering the first oxide layer 130a and the second oxide layer 130. As a result, the memory device 100 of FIG. 1 can be obtained. In some embodiments, the first gate structure 120a and the second gate structure 120b are made of a material including tungsten, but the present disclosure is not limited in this regard. In addition, horizontal portions of the first oxide layer 130a and the second oxide layer 130 on the top surface 1126 of the substrate 110 may be removed. Contact structures and capacitors may be formed above the first source/drain region 1122a, the second source/drain region 1122b, and the third source/drain region 1122c as described in FIG. 1.

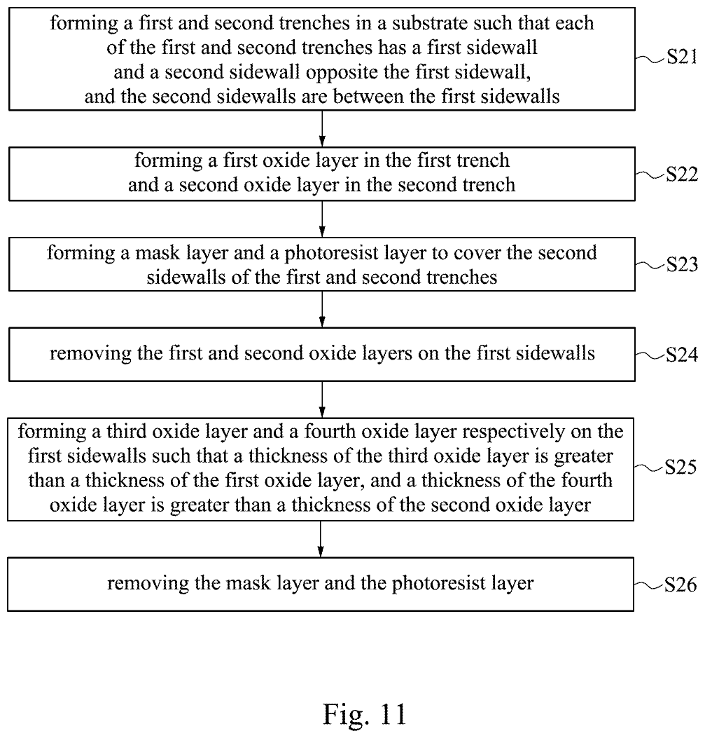

FIG. 11 is a flow chart of a method of forming a memory device according to some embodiments of the present disclosure. The method starts with step S21 in which a first trench and a second trench are formed in a substrate such that each of the first and second trenches has a first sidewall and a second sidewall opposite the first sidewall, and the second sidewalls are between the first sidewalls. Thereafter, in step S22, a first oxide layer is formed in the first trench and a second oxide layer is formed in the second trench. Next, in step S23, a mask layer and a photoresist layer are formed to cover the second sidewalls of the first and second trenches. Afterwards, in step S24, the first and second oxide layers on the first sidewalls are removed. Subsequently, in step S25, a third oxide layer and a fourth oxide layer are respectively formed on the first sidewalls such that a thickness of the third oxide layer is greater than a thickness of the first oxide layer, and a thickness of the fourth oxide layer is greater than a thickness of the second oxide layer. Next, in step S26, the mask layer and the photoresist layer are removed.

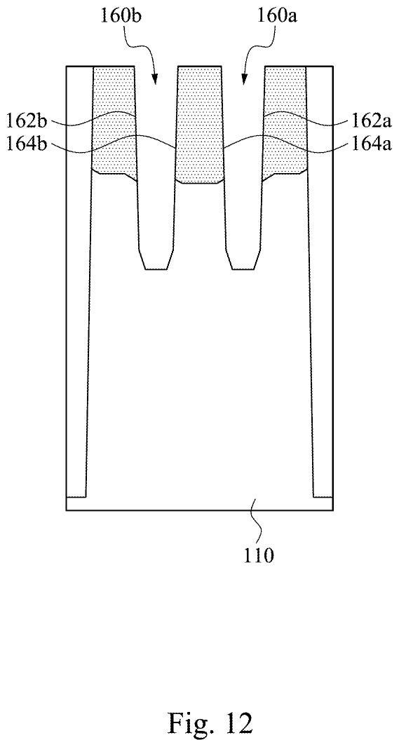

FIGS. 12-19 are cross-sectional views of a method of forming a memory device at different mediate stage according to some embodiments of the present disclosure s. Reference is made to FIG. 12 and step S21 of FIG. 11. The first trench 160a and the second trench 160b are formed in the substrate 110. The first trench 160a includes the first sidewall 162a and the second sidewall 164a, and the second trench 160b includes the first sidewall 162b and the second sidewall 164b as described in FIG. 3.

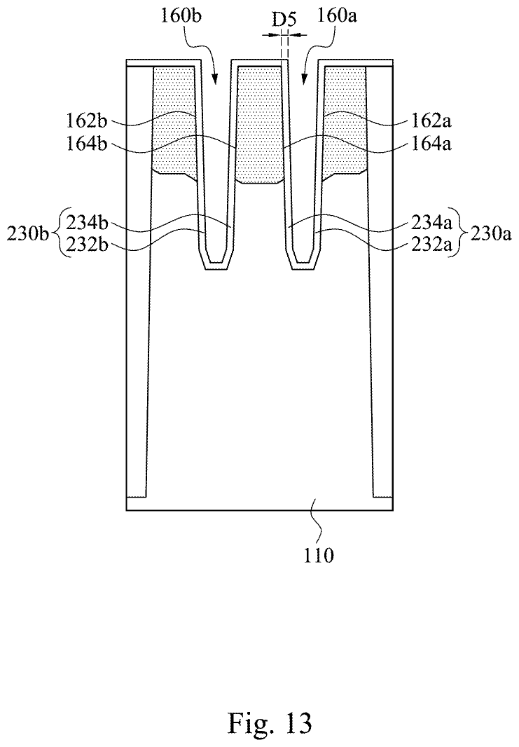

Reference is made to FIG. 13 and step S22 of FIG. 11. A first oxide layer 230a and a second oxide layer 230b are respectively formed in the first trench 160a and the second trench 160b. The first oxide layer 230a includes a first portion 232a located on the first sidewall 162a of the first trench 160a, and a second portion 234a located on the second sidewall 164a of the first trench 160a. The second oxide layer 230b includes a first portion 232b located on the first sidewall 162b of the second trench 160b, and a second portion 234b located on the second sidewall 164b of the second trench 160b. Each of the first portions 232a, 232b and the second portions 234a, 234b has a thickness D5 that are substantially the same.

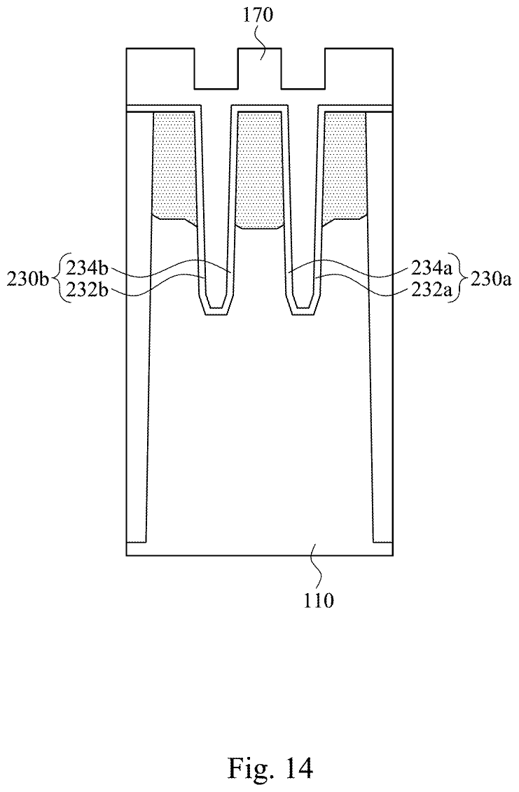

Reference is made to FIG. 14. The mask layer 170 is formed to cover the first oxide layer 230a and the second oxide layer 230b.

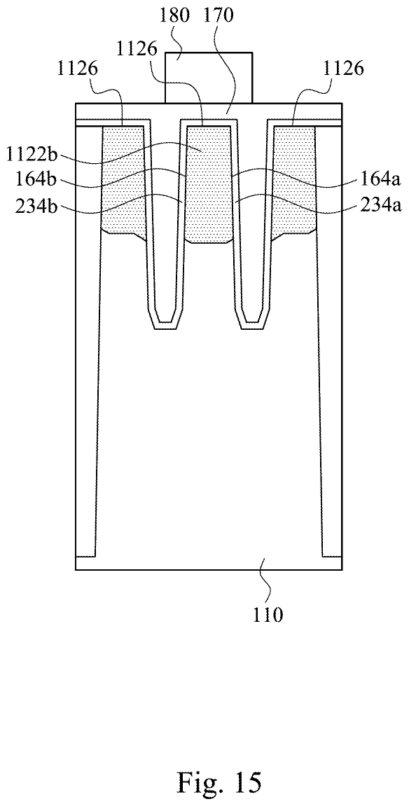

Reference is made to FIG. 15 and step S23 of FIG. 11. The mask layer 170 is polished while the top surface 1126 of the substrate 110 is still covered by the mask layer 170. After the mask layer 170 is polished, a photoresist layer 180 is formed on the mask layer 170. The photoresist layer 180 covers a portion of the mask layer 170 overlying the second portion 234a of the first oxide layer 230a, the second portion 234b of the second oxide layer 230b, and the second source/drain region 1122b. In other words, the portion of the mask layer 170 that is below the photoresist layer 180 covers the second sidewall 164a of the first trench 160a and the second sidewall 164b of the second trench 160b.

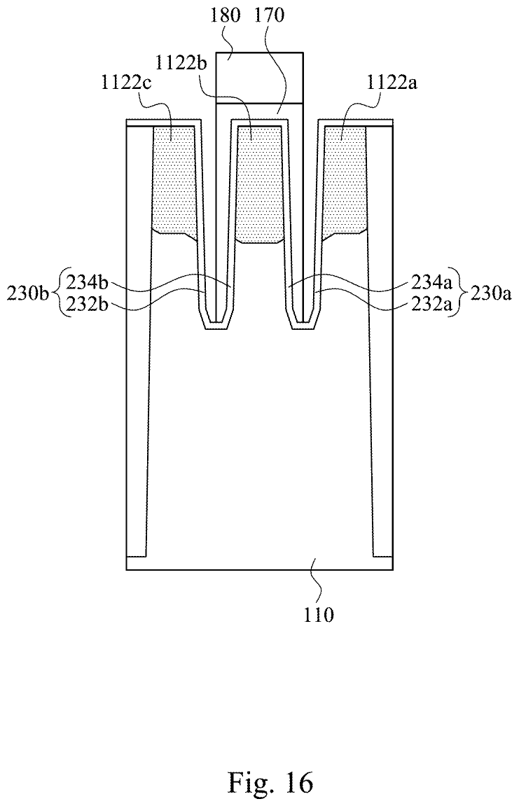

Reference is made to FIG. 16 and step S23 of FIG. 11. After the photoresist layer 180 is formed, the portion of the mask layer 170 overlying the first source/drain region 1122a, third source/drain region 1122c, the first portion 232a of the first oxide layer 230a, and the first portion 232b of the second oxide layer 230b are removed by etching. In other words, the mask layer 170 that is not covered by the photoresist layer 180 is removed, and the first portion 232a of the first oxide layer 230a and the first portion 232b of the second oxide layer 230b are exposed.

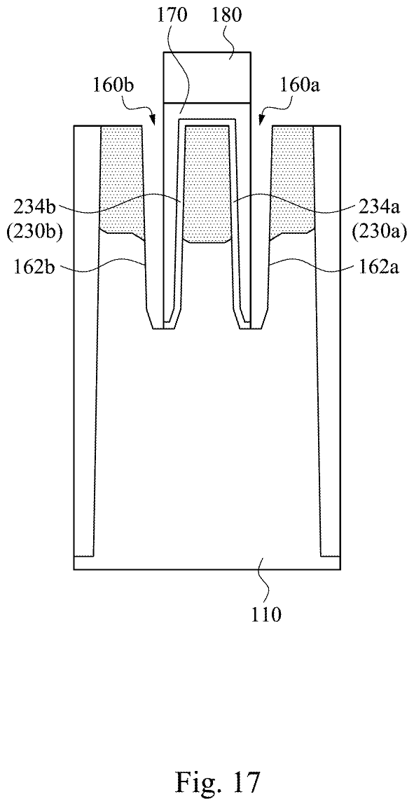

Reference is made to FIG. 16, FIG. 17 and step S24 of FIG. 11. The first portion 232a of the first oxide layer 230a and the first portion 232b of the second oxide layer 230b are removed. Therefore, the first sidewall 162a of the first trench 160a and the first sidewall 162b of the second trench 160b are respectively spaced apart from the first oxide layer 230a and the second oxide layer 230b.

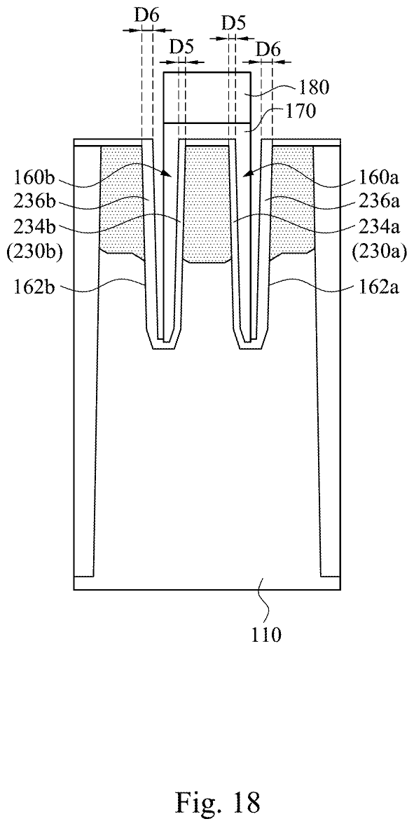

Reference is made to FIG. 18 and step S25 of FIG. 11. A third oxide layer 236a is formed on the first sidewall 162a of the first trench 160a, and a fourth oxide layer 236b is formed on the first sidewall 162b of the second trench 160b. Each of the third oxide layer 236a and the fourth oxide layer 236b has a thickness D6 that is greater than the thickness D5 of the second portion 234a of the first oxide layer 230a and the second portion 234b of the second oxide layer 230b.

In the present embodiment, the third oxide layer 236a extend to a bottom of the first trench 160a, and the fourth oxide layer 236b extend to a bottom of the second trench 160b. In other words, the third oxide layer 236a on the bottom of the first trench 160a may be in contact with the mask layer 170 that covers the first oxide layer 230a, and the fourth oxide layer 236b on the bottom of the second trench 160b may be in contact with the mask layer that covers the second oxide layer 230b.

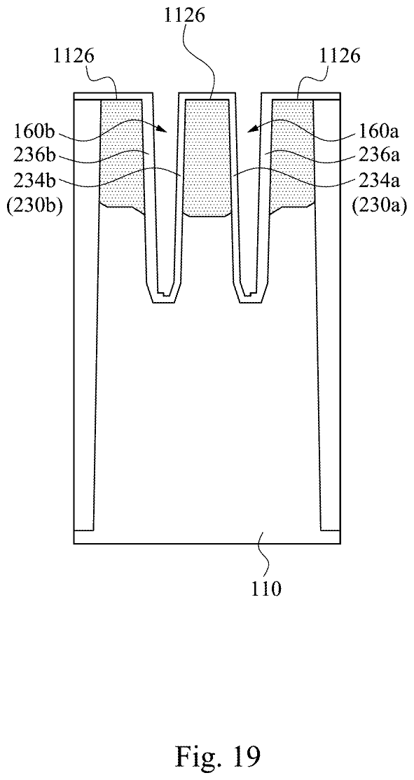

Reference is made to FIG. 18, FIG. 19 and step S26 of FIG. 11. The mask layer 170 and the photoresist layer 180 are removed. Therefore, the first oxide layer 230a and the third oxide layer 236a collectively cover the first trench 160a, and the second oxide layer 230b and the fourth oxide layer 236b collectively cover the second trench 160b.

In the subsequent process, the first gate structure 120a and the second gate structure 120b of FIG. 1 may be respectively formed in the first trench 160a and the second trench 160b, and then the first dielectric layer 140a and the second dielectric layer 140b of FIG. 1 may be respectively formed on the first gate structure 120a and the second gate structure 120b, thereby covering the combination of the first oxide layer 230a and the third oxide layer 236a and the combination of the second oxide layer 230b and the fourth oxide layer 236b. As a result, a memory device can be obtained. In some embodiments, the first gate structure 120a and the second gate structure 120b are made of a material including tungsten, but the present disclosure is not limited in this regard. In addition, horizontal portions of the first oxide layer 130a, second oxide layer 130b, the third oxide layer 236a, and the fourth oxide layer 236 on the top surface 1126 of the substrate 110 may be removed. Contact structures and capacitors may be formed above the first source/drain region 1122a, the second source/drain region 1122b, and the third source/drain region 1122c as described in FIG. 1.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device comprising:
a substrate having a first protruding portion and a second protruding portion adjacent to the first protruding portion;
a first gate structure on the substrate and between the first and second protruding portions; and
a first oxide layer disposed between the substrate and the first gate structure, and comprising a first portion and a second portion, wherein the first portion is between the first gate structure and the first protruding portion, the second portion is between the first gate structure and the second protruding portion, and a thickness of the first portion is greater than a thickness of the second portion.

2. The memory device of claim 1, wherein the first protruding portion and the second protruding portion respectively have a first and second source/drain regions, and the first and second portions of the first oxide layer respectively extend to sidewalls of the first and second source/drain regions.

3. The memory device of claim 1, wherein the first portion of the first oxide layer extends to a bottom of the first gate structure.

4. The memory device of claim 1, further comprising:
a dielectric layer on the first gate structure, wherein the first and second portions of the first oxide layer extend to sidewalls of the dielectric layer.

5. The memory device of claim 4, wherein the dielectric layer is between the first and second portions of the first oxide layer.

6. The memory device of claim 4, wherein the first protruding portion and the second protruding portion respectively have a first and second source/drain regions, and each of the first and second portions of the first oxide layer is between the dielectric layer and one of the first and second source/drain regions.

7. The memory device of claim 1, wherein the substrate further has a third protruding portion adjacent to the second protruding portion, and the memory device further comprises:
a second gate structure on the substrate and between the second and third protruding portions; and
a second oxide layer disposed between the substrate and the second gate structure, and comprising a first portion and a second portion, wherein the first and second portions of the second oxide layer have different thickness.

8. The memory device of claim 7, wherein the first portion of the second oxide layer is between the second gate structure and the third protruding portion, the second portion of the second oxide layer is between the second gate structure and the second protruding portion, and a thickness of the first portion of the second oxide layer is greater than a thickness of the second portion of the second oxide layer.

9. The memory device of claim 7, wherein the third protruding portion has a third source/drain region, and the first and second portions of the second oxide layer respectively extend to sidewalls of the third source/drain region and the second source/drain region.

10. The memory device of claim 7, wherein the second portion of the first oxide layer and the second portion of the second oxide layer are located on two opposite sidewalls of the second protruding portion.

11. A method of forming a memory device, the method comprising:
forming a first trench and a second trench in a substrate such that each of the first and second trenches has a first sidewall and a second sidewall opposite the first sidewall, wherein the second sidewalls are between the first sidewalls;
forming a mask layer to cover the first trench and the second trench;
performing an ion implantation into first sidewalls of the first and second trenches;
removing the mask layer; and
forming a first oxide layer and a second oxide layer respectively in the first and second trenches such that thicknesses of the first and second oxide layers on the first sidewalls of the first and second trenches are greater than thicknesses of the first and second oxide layers on the second sidewalls of the first and second trenches.

12. The method of claim 11, wherein forming the mask layer further comprises:
forming the mask layer over a top surface of the substrate; and
polishing the mask layer.

13. The method of claim 12, wherein forming the mask layer further comprises:
after polishing the mask layer, forming a photoresist layer on the mask layer that covers the first trench and the second trench.

14. The method of claim 13, wherein forming the mask layer further comprises:
after forming the photoresist layer, removing the mask layer not covered by the photoresist layer.

15. The method of claim 14, further comprising:
after performing the ion implantation, removing the photoresist layer.

16. The method of claim 11, wherein the ion implantation is performed by using fluorine.

17. A method of forming a memory device, the method comprising:
forming a first and second trenches in a substrate such that each of the first and second trenches has a first sidewall and a second sidewall opposite the first sidewall, wherein the second sidewalls are between the first sidewalls;
forming a first oxide layer in the first trench and a second oxide layer in the second trench;
forming a mask layer and a photoresist layer to cover the second sidewalls of the first and second trenches;
removing the first and second oxide layers on the first sidewalls;
forming a third oxide layer and a fourth oxide layer respectively on the first sidewalls such that a thickness of the third oxide layer is greater than a thickness of the first oxide layer, and a thickness of the fourth oxide layer is greater than a thickness of the second oxide layer; and
removing the mask layer and the photoresist layer.

18. The method of claim 17, wherein forming the mask layer and the photoresist layer further comprises:
forming the mask layer over the first oxide layer and the second oxide layer; and
polishing the mask layer.

19. The method of claim 18, wherein forming the mask layer and the photoresist layer further comprises:
after polishing the mask layer, forming the photoresist layer on the mask layer that covers the second sidewalls of the first and second trenches.

20. The method of claim 19, wherein forming the mask layer and the photoresist layer further comprises:
after forming the photoresist layer, removing the mask layer not covered by the photoresist layer.
